(19) United States
(12) Patent Application Publication
(10) Pub. No.: US 2026/0280549 A1
(43) Pub. Date: Sep. 17, 2026

(54) GATE DRIVER CIRCUIT

(71) Applicant: ROHM CO., LTD., Kyoto (JP)

(72) Inventors: Yuichi SHINOZAKI, Kyoto (JP); Taketo TSUKASA, Kyoto (JP)

(21) Appl. No.: 19/677,855

(22) Filed: May 14, 2026

Related U.S. Application Data
(63) Continuation of application No. PCT/JP2024/039481, filed on Nov. 6, 2024.

(30) Foreign Application Priority Data
Nov. 17, 2023 (JP) 2023-195712

(51) Int. Cl. H03K 17/0814; H02M 1/088

(52) U.S. Cl. CPC H03K 17/08142; H02M 1/088; H03K 2217/0063; H03K 2217/0072

(57) ABSTRACT

A gate driver circuit drives an N-type power transistor based on a control signal. A first transistor is connected between a high-side line and an output line. A second transistor is connected between the output line and a low-side line. A third transistor is connected between the output line and the low-side line in parallel with the second transistor. An auxiliary circuit turns on the third transistor for a predetermined period when the control signal transitions from an off-level to an on-level.

### TECHNICAL FIELD

The present disclosure relates to a gate driver circuit.

### DESCRIPTION OF RELATED ART

In the field of power electronics, including DC/DC converters, AC/DC converters, and inverters, switching circuits such as half-bridge circuits and full-bridge circuits are used.

The switching circuit includes an N-type power transistor and a gate driver circuit that drives the power transistor. Here, the gate driver circuit switches a gate-source voltage of the power transistor between a low-level voltage and a high-level voltage to switch between an ON state and an OFF state.

The gate driver circuit outputs the high-level voltage when turning on the power transistor. The gate of the power transistor is charged by the high-level voltage, and when the gate-source voltage of the power transistor exceeds a threshold voltage, the power transistor turns on. In a turn-on operation of the power transistor, if a parasitic inductor exists on a path of a current supplied to the gate, the gate voltage overshoots. If the overshoot is too large, there is a possibility that a breakdown voltage of the power transistor may be exceeded.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures.

FIG. 1 is a block diagram of a switching circuit including a gate driver circuit according to an embodiment.

FIG. 2 is a waveform diagram for explaining an operation of a gate driver circuit according to a comparative technique.

FIG. 3 is a waveform diagram for explaining an operation of the switching circuit of FIG. 1.

FIG. 4 is a circuit diagram showing a configuration example of an auxiliary circuit.

FIG. 5 is a circuit diagram showing another configuration example of an auxiliary circuit.

FIG. 6 is a circuit diagram showing another configuration example of an auxiliary circuit.

FIG. 7 is a circuit diagram showing a specific example of the auxiliary circuit of FIG. 6.

FIG. 8 is a circuit diagram showing a modification of the gate driver circuit.

FIG. 9 is a circuit diagram of a switching circuit including a gate driver circuit.

### DETAILED DESCRIPTION

### Overview of Embodiments

An overview of several exemplary embodiments of the present disclosure will be described. This overview briefly describes some concepts of one or more embodiments for the purpose of basic understanding of the embodiments as a preamble to the detailed description to be described later, and does not limit the breadth of the invention or disclosure. This overview is not a comprehensive overview of all possible embodiments, and is not intended to identify critical elements of all embodiments or to delineate the scope of some or all aspects. For convenience, "an embodiment" may be used to refer to one embodiment (example or modification) or a plurality of embodiments (examples or modifications) disclosed in the present specification.

A gate driver circuit according to an embodiment drives an N-type power transistor based on a control signal. The gate driver circuit includes a low-side line connected to a source of the power transistor, an output line connected to a gate of the power transistor, a high-side line in which a high-level voltage higher than a voltage of the low-side line is generated, a first transistor connected between the high-side line and the output line, a second transistor connected between the output line and the low-side line, a third transistor connected between the output line and the low-side line in parallel with the second transistor, a pre-driver configured to turn on the first transistor and turn off the second transistor when the control signal is at an on-level indicating to turn on the power transistor and turn off the first transistor and turn on the second transistor when the control signal is at an off-level indicating to turn off the power transistor, and an auxiliary circuit configured to turn on the third transistor for a predetermined period when the control signal transitions from the off-level to the on-level.

According to this embodiment, after the first transistor is turned on, the third transistor is turned on during a period in which an overshoot may occur and is kept on for a predetermined period, whereby a part of a current flowing into the gate of the power transistor can be sunk to another path, and the overshoot of the gate voltage can be suppressed.

In one embodiment, the auxiliary circuit may include a pulse generator configured to generate a pulse signal having a pulse width corresponding to the predetermined period.

In one embodiment, a high level of the pulse signal is the high-level voltage, and the pulse signal may be supplied to a gate of the third transistor.

In one embodiment, the auxiliary circuit may further include a buffer having an input receiving the pulse signal and an output connected to the gate of the third transistor.

In one embodiment, the buffer may include a CMOS inverter having a power supply terminal connected to the output line and an output connected to the gate of the third transistor.

In one embodiment, the auxiliary circuit may further include a level shifter having an input receiving the pulse signal and an output connected to the gate of the third transistor, the level shifter being configured to level-shift the high level of the pulse signal to an intermediate-level voltage lower than the high-level voltage. In this configuration, an amount of a sink current drawn by the third transistor can be optimized according to the intermediate-level voltage.

In one embodiment, the level shifter may include a constant voltage element having a first end connected to the output line and a CMOS inverter having a power supply terminal connected to a second end of the constant voltage element and an output connected to the gate of the third transistor. The constant voltage element may be a diode.

In one embodiment, the auxiliary circuit may further include a MOS transistor connected between a drain of the third transistor and the output line and having a gate and a drain connected to each other. By adding the MOS transistor, the amount of the sink current can be adjusted according to a size of the MOS transistor.

In one embodiment, the predetermined period may be 1 to 20 ns.

In one embodiment, the gate driver circuit may be monolithically integrated on a single semiconductor substrate. The "monolithic integration" includes a case where all of components of a circuit are formed on a semiconductor substrate and a case where main components of a circuit are monolithically integrated, and some resistors, capacitors, and the like for adjusting circuit constants may be provided outside the semiconductor substrate. By integrating the circuit on one chip, a circuit area can be reduced and characteristics of circuit elements can be kept uniform.

A switching circuit according to an embodiment may include a power transistor and any of the gate driver circuits described above that drives the power transistor.

### Embodiments

Hereinafter, preferred embodiments will be described with reference to the drawings. The same or equivalent constituent elements, members, and processes shown in each drawing are denoted by the same reference numerals, and redundant description will be omitted as appropriate. In addition, the embodiments are illustrative and do not limit the disclosure and the invention, and all features and combinations thereof described in the embodiments are not necessarily essential to the disclosure and the invention.

In the present specification, "a state in which a member A is connected to a member B" includes not only a case where the member A and the member B are physically and directly connected, but also a case where the member A and the member B are indirectly connected via another member that does not substantially affect their electrical connection state or does not impair functions and effects achieved by their coupling.

Similarly, "a state in which a member C is connected (provided) between a member A and a member B" includes not only a case where the member A and the member C, or the member B and the member C are directly connected, but also a case where they are indirectly connected via another member that does not substantially affect their electrical connection state or does not impair functions and effects achieved by their coupling.

Further, in the present specification, reference numerals assigned to electrical signals such as voltage signals and current signals, or circuit elements such as resistors, capacitors, and inductors shall represent their respective voltage values, current values, or circuit constants (resistance values, capacitance values, inductance) as necessary.

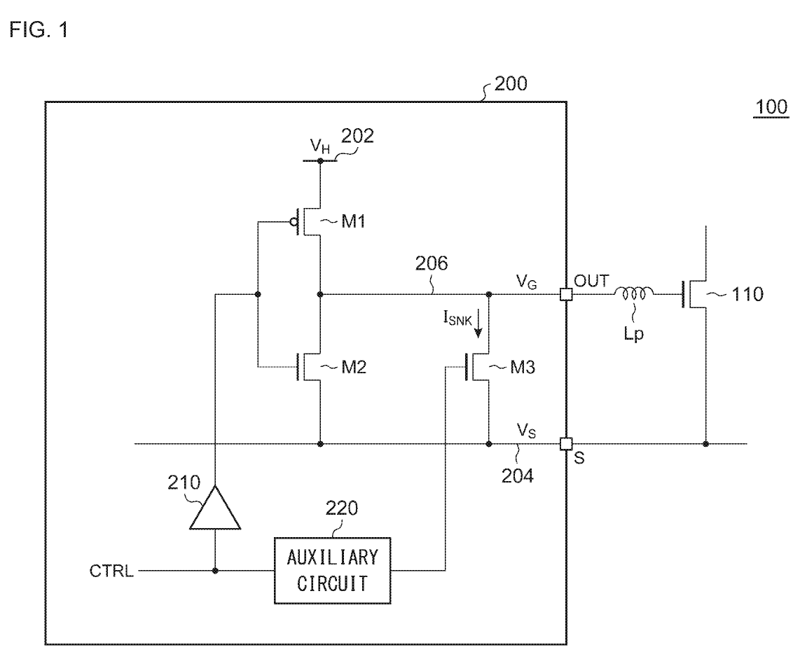

FIG. 1 is a block diagram of a switching circuit 100 including a gate driver circuit 200 according to an embodiment. The switching circuit 100 includes an N-type power transistor 110 and the gate driver circuit 200.

The gate driver circuit 200 drives the power transistor 110 based on a control signal CTRL. The control signal CTRL switches between an on-level (for example, a high level) indicating an ON state of the power transistor 110 and an off-level (for example, a low level) indicating an OFF state of the power transistor 110.

The gate driver circuit 200 includes a high-side line 202, a low-side line 204, an output line 206, a first transistor M1, a second transistor M2, a third transistor M3, a pre-driver 210, and an auxiliary circuit 220. The gate driver circuit 200 is an integrated circuit (IC) monolithically integrated on a single semiconductor substrate.

An output pin OUT of the gate driver circuit 200 is connected to the gate of the power transistor 110. The output line 206 is connected to the gate of the power transistor 110 via the output pin OUT. In practice, bonding wires, via holes, and wirings (not shown) are connected to the output pin OUT, and these serve as a parasitic inductor Lp.

A source pin S is connected to the source of the power transistor 110. The low-side line 204 is connected to the source of the power transistor 110 via the source pin S. A voltage of the low-side line 204 is denoted by V_{S}. When the power transistor 110 is a low-side transistor, the voltage V_{S} is 0 V, and when the power transistor 110 is a high-side transistor, the voltage V_{S} is a switching voltage that switches between 0 V and an input voltage of the switching circuit 100.

A high-level voltage V_{H} to be applied to the gate of the power transistor 110 is supplied to the high-side line 202. The high-level voltage V_{H} is a voltage higher than the voltage V_{S} of the low-side line 204 by a predetermined voltage ΔV.

The first transistor M1 is a PMOS transistor and is connected between the high-side line 202 and the output line 206. The second transistor M2 is an NMOS transistor and is connected between the output line 206 and the low-side line 204.

The third transistor M3 is connected between the output line 206 and the low-side line 204 in parallel with the second transistor M2.

The pre-driver 210 turns on the first transistor M1 and turns off the second transistor M2 when the control signal CTRL is at the on-level. The pre-driver 210 turns off the first transistor M1 and turns on the second transistor M2 when the control signal CTRL is at the off-level.

The auxiliary circuit 220 turns on the third transistor M3 for a predetermined period T when the control signal CTRL enters the on-level from the off-level. When the third transistor M3 is turned on, a current I_{SNK} is sunk from the output line 206.

The configuration of the switching circuit 100 has been described above. Next, an operation of the switching circuit 100 will be described. Advantages of the gate driver circuit 200 will become clear by comparison with a comparative technique. Therefore, the comparative technique will be described.

A gate driver circuit according to a comparative technique has a configuration in which the third transistor M3 and the auxiliary circuit 220 are omitted from the gate driver circuit 200 of FIG. 1. An operation of the gate driver circuit according to the comparative technique will be described.

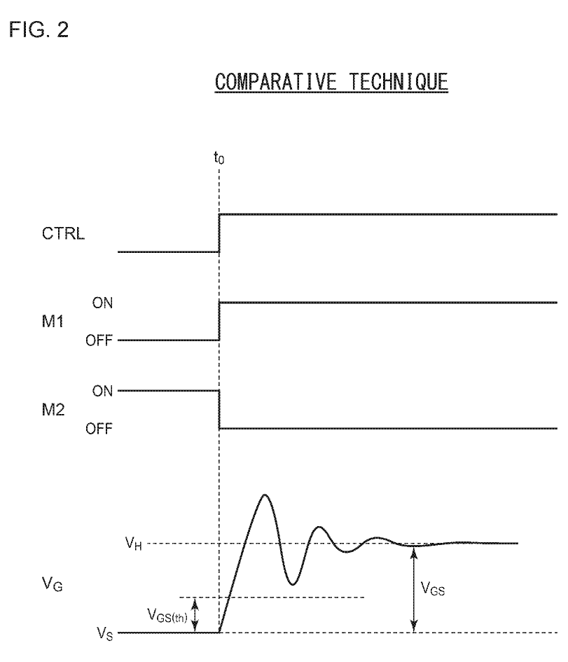

FIG. 2 is a waveform diagram for explaining the operation of the gate driver circuit according to the comparative technique. FIG. 2 shows the control signal CTRL, the first transistor M1, the second transistor M2, and a gate voltage V_{G} of the power transistor 110.

Before time t₀, the control signal CTRL is at an off-level (low level), the first transistor M1 is off, and the second transistor M2 is on. Since the second transistor M2 is on, the output voltage V_{G} of the gate driver circuit 200, that is, the gate voltage V_{G} of the power transistor 110, is equal to the voltage V_{S} of the low-side line 204, a gate-source voltage V_{GS} of the power transistor 110 is 0 V, and the power transistor 110 is held in the Off state.

When the control signal CTRL enters the on-level from the off-level at time t₀, the first transistor M1 is turned on and the second transistor M2 is turned off. As the first transistor M1 is turned on, the output voltage V_{G} of the gate driver circuit 200 increases toward the high-level voltage V_{H}.

As the rapidly increasing output voltage V_{G} is applied to the parasitic inductor Lp, an overshoot of the gate-source voltage V_{GS}, and a subsequent undershoot and ringing are caused. If the overshoot of the gate-source voltage V_{GS} exceeds the breakdown voltage of the power transistor 110, it causes a decrease in reliability of the power transistor 110. Further, if the gate-source voltage V_{GS} falls below the gate-source threshold voltage V_{GS(th)} due to the undershoot, the power transistor 110 is turned off. The above is the problem occurring in the gate driver circuit according to the comparative technique. Returning to the embodiment.

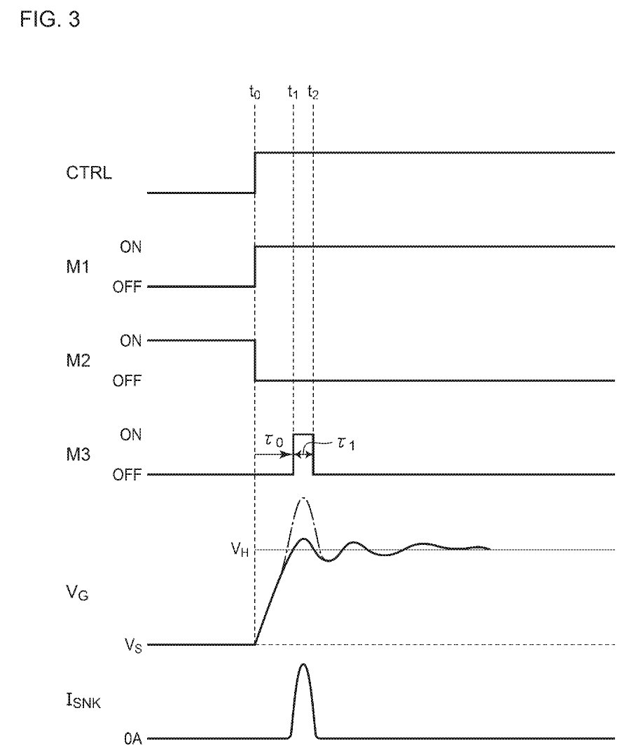

FIG. 3 is a waveform diagram for explaining the operation of the switching circuit 100 of FIG. 1. FIG. 3 shows the control signal CTRL, states of the first transistor M1, the second transistor M2, and the third transistor M3, the output voltage V_{G} of the gate driver circuit 200, and a sink current I_{SNK} flowing through the third transistor M3. Note that a waveform of the output voltage V_{G} in the comparative technique is indicated by a dashed-dotted line.

Before time t₀, the control signal CTRL is at the off-level (low level), the first transistor M1 is off, and the second transistor M2 is on. The third transistor M3 is off. Since the second transistor M2 is on, the output voltage V_{G} of the gate driver circuit 200, that is, the gate voltage V_{G} of the power transistor 110, is equal to the voltage V_{S} of the low-side line 204, the gate-source voltage V_{GS} of the power transistor 110 is 0 V, and the power transistor 110 is fixed to be off.

When the control signal CTRL enters the on-level from the off-level at time t₀, the first transistor M1 is turned on and the second transistor M2 is turned off. As the first transistor M1 is turned on, the output voltage V_{G} of the gate driver circuit 200 increases toward the high-level voltage V_{H}.

The third transistor M3 is turned on at time t₁ after a delay time τ₁ has elapsed from time t₀, remains in an ON state for a predetermined time τ₂ thereafter, and is turned off at time t₂. A combination of lengths of the delay time τ₁ and the predetermined time τ₂ can be determined based on a period in which an overshoot may occur in the comparative technique.

By turning on the third transistor M3 during the period in which the overshoot may occur, a part of a current attempting to flow into the gate of the power transistor 110 flows into the third transistor M3 as the sink current I_{SNK} and is diverted to the source of the power transistor 110. Thereby, the overshoot of the output voltage V_{G} of the gate driver circuit 200 is suppressed, and the subsequent undershoot and ringing are also suppressed.

The above is the operation and effect of the gate driver circuit 200.

The present disclosure extends to various apparatuses and methods perceived as the block diagram or the circuit diagram of FIG. 1 or derived from the above description, and is not limited to a specific configuration. Hereinafter, more specific configuration examples and examples will be described not to narrow the scope of the present disclosure but to help understanding and to clarify the essence and operation of the present disclosure and the invention of the present disclosure.

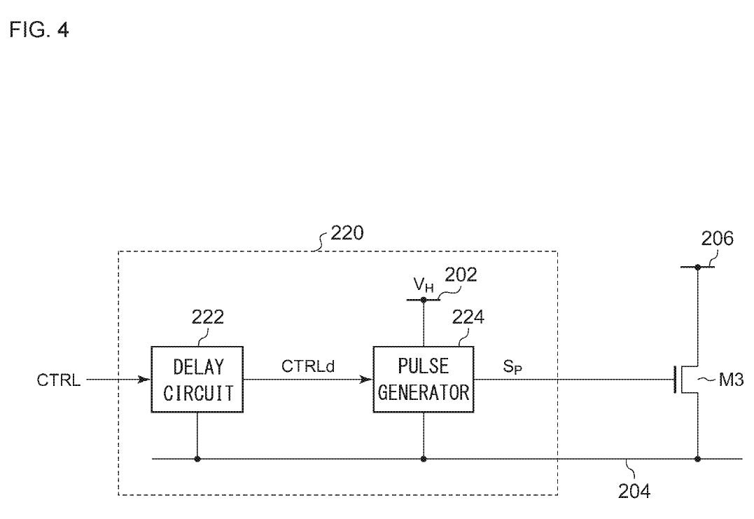

FIG. 4 is a circuit diagram showing a configuration example of the auxiliary circuit 220. The auxiliary circuit 220 includes a delay circuit 222 and a pulse generator 224. The delay circuit 222 delays the control signal CTRL by a delay time τ₁. The pulse generator 224 receives the delayed control signal CTRLd, generates a pulse signal Sp having a pulse width corresponding to a predetermined time τ₂, and supplies the pulse signal Sp to the gate of the third transistor M3. In this configuration, a high level of the pulse signal Sp is equal to the high-level voltage V_{H}.

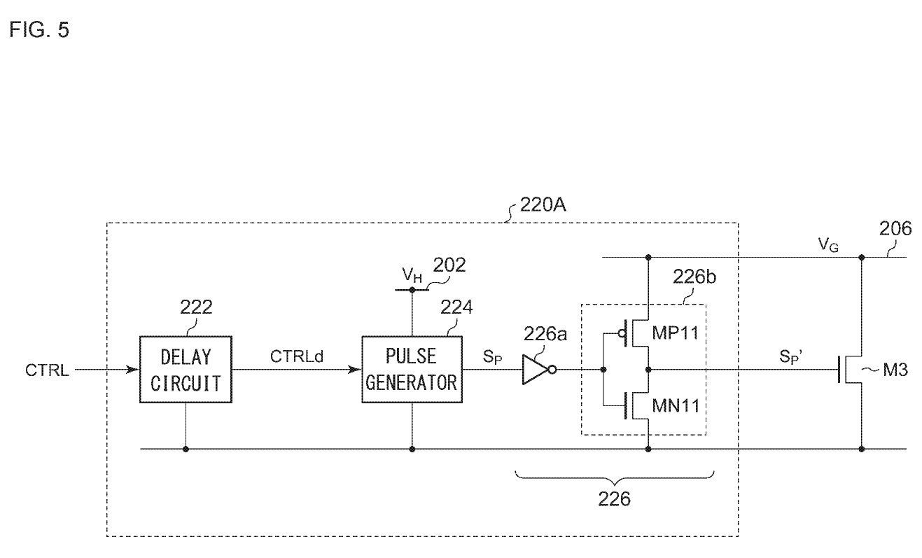

FIG. 5 is a circuit diagram showing another configuration example (220A) of the auxiliary circuit 220. The auxiliary circuit 220A includes a buffer 226 in addition to the delay circuit 222 and the pulse generator 224. The buffer 226 receives the pulse signal Sp at its input node, and its output node is connected to the gate of the third transistor M3.

For example, the buffer 226 is composed of two stages of CMOS inverters 226a and 226b. Each of the CMOS inverters 226a and 226b is composed of a CMOS inverter including a PMOS transistor MP11 and an NMOS transistor MN11. A power supply terminal of the CMOS inverter 226b, that is, a source of the PMOS transistor MP11, is connected to the output line 206. In a period in which the output pulse Sp is generated, the voltage V_{G} of the output line 206 is in the vicinity of the high-level voltage V_{H}.

Note that the source of the PMOS transistor MP11 may be connected to the high-side line 202.

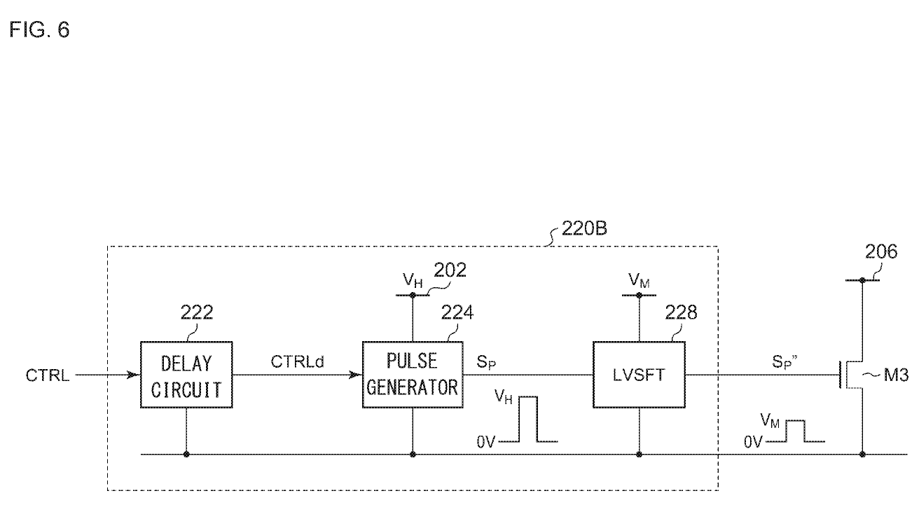

FIG. 6 is a circuit diagram showing another configuration example (220B) of the auxiliary circuit 220. A level shifter 228 level-shifts the high level of the pulse signal Sp to an intermediate-level voltage V_{M} lower than the high-level voltage V_{H}. The level-shifted pulse signal Sp'' is supplied to the gate of the third transistor M3.

In the configuration of FIG. 4 or FIG. 5, the high-level voltage V_{H} is applied to the gate of the third transistor M3. Therefore, in an application where the high-level voltage V_{H} is high, there is a possibility that the amount of the sink current I_{SNK} flowing through the third transistor M3 becomes too large. According to the configuration of FIG. 6, the amount of the sink current I_{SNK} flowing through the third transistor M3 can be optimized according to the intermediate-level voltage V_{M}.

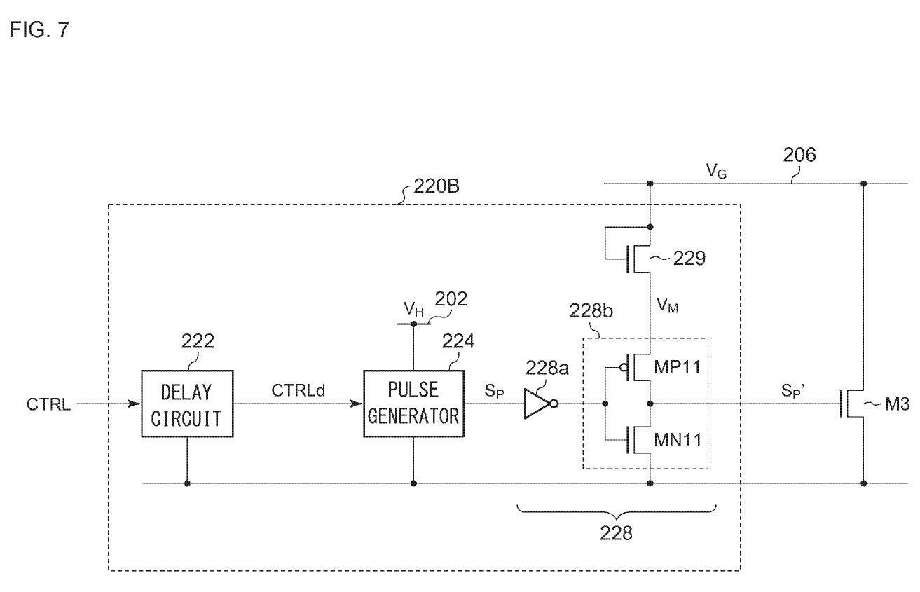

FIG. 7 is a circuit diagram showing a specific example of the auxiliary circuit 220B of FIG. 6. The level shifter 228 includes a CMOS inverter 228a, a CMOS inverter 228b, and a constant voltage element 228c. A first end of the constant voltage element 228c is connected to the output line 206. The constant voltage element 228c is, for example, a diode. In this example, a so-called diode-connected NMOS transistor in which a gate and a drain are connected to each other is used as the constant voltage element 228c. Note that the constant voltage element 228c may be any element that generates a substantially constant voltage drop, and for example, a resistor may be used.

A power supply terminal of the CMOS inverter 228b, that is, a source of the PMOS transistor MP11, is connected to a second end of the constant voltage element 228c. An intermediate-level voltage of V_{M} = V_{G} - V_{F} is generated at the second end of the constant voltage element 228c. V_{F} is a voltage drop of the constant voltage element 228c, and since V_{H} ≈ V_{G}, V_{M} < V_{H} holds. An output of the CMOS inverter 228b is connected to the gate of the third transistor.

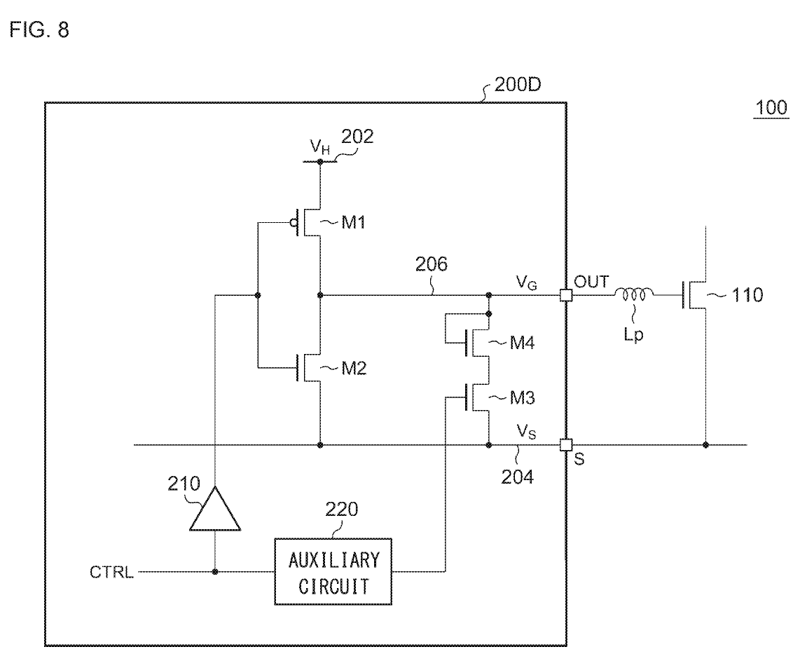

FIG. 8 is a circuit diagram showing a modification (200D) of the gate driver circuit 200. The gate driver circuit 200D further includes a constant voltage element 230. As the constant voltage element 230, a MOS transistor in which a gate and a drain are connected to each other can be used. Note that a diode or a resistor may be used as the constant voltage element 230 instead.

By inserting the constant voltage element 230, the sink current I_{SNK} flowing when the third transistor M3 is on can be adjusted.

### Applications

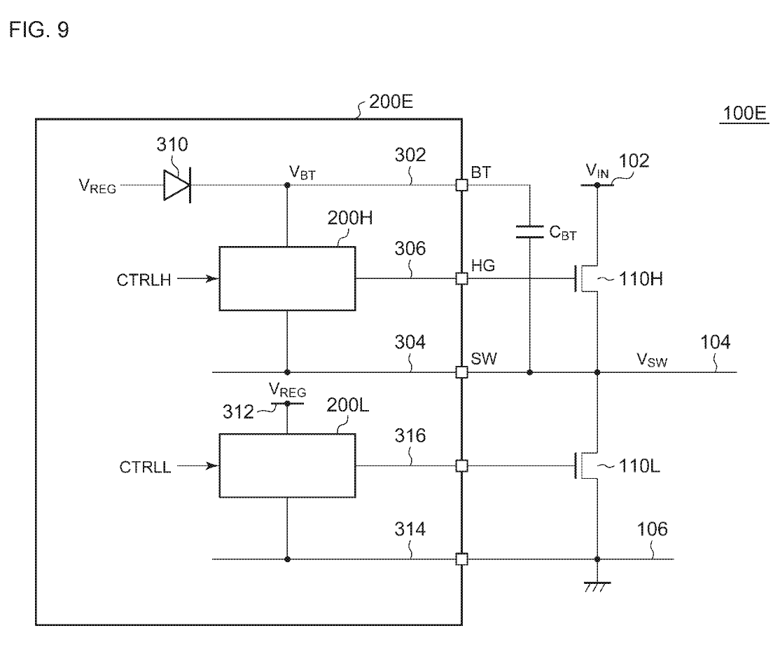

FIG. 9 is a circuit diagram of a switching circuit 100E including a gate driver circuit 300. The switching circuit 100E includes a high-side transistor 110H, a low-side transistor 110L, the gate driver circuit 300, and a bootstrap capacitor C_{BT}.

The high-side transistor 110H and the low-side transistor 110L are NMOS transistors and constitute a half-bridge circuit. The high-side transistor 110H is connected between an input line 102 and a switching line 104, and the low-side transistor 110L is connected between the switching line 104 and a ground line 106.

The gate driver circuit 300 is an integrated circuit (IC) that controls states of the high-side transistor 110H and the low-side transistor 110L, and controls an electrical state (switching voltage) V_{SW} of the switching line 104.

A gate of the high-side transistor 110H is connected to a high-side gate pin HG of the gate driver circuit 300, and a gate of the low-side transistor 110L is connected to a low-side gate pin LG. A switching pin SW is connected to the switching line 104, and a ground pin GND is connected to the ground line 106. A bootstrap capacitor C_{BT} is connected between a bootstrap pin BT and the switching pin SW.

The gate driver circuit 300 includes a high-side driver 200H that drives the high-side transistor 110H and a low-side driver 200L that drives the low-side transistor 110L.

A bootstrap line 302 is connected to the bootstrap pin BT. A switching line 304 is connected to the switching pin SW. A high-side gate line 306 is connected to the high-side gate pin HG. A constant voltage V_{REG} is applied to the bootstrap line 302 via a rectifying element 310 such as a diode. The rectifying element 310 and the bootstrap capacitor C_{BT} form a bootstrap circuit, and generate a bootstrap voltage V_{BT}, which is higher than the switching line 304 by the constant voltage V_{REG}, on the bootstrap line 302.

The high-side driver 200H drives the high-side transistor 110H based on a high-side control signal CTRLH.

A power supply voltage VDD is supplied to a power supply line 312, and a ground line 314 is connected to the ground pin GND. A low-side gate line 316 is connected to the low-side gate pin LG.

The low-side driver 200L drives the low-side transistor 110L based on a low-side control signal CTRLL.

Each of the high-side driver 200H and the low-side driver 200L can be configured by the gate driver circuit 200 described with reference to FIGS. 1 to 8.

For example, the switching circuit 100E may be a part of a switching power supply including a DC/DC converter.

Alternatively, the switching circuit 100E may be a three-phase inverter, a motor driver, or the like.

Although the embodiments according to the present disclosure have been described using specific terms, the description is merely illustrative for the purpose of helping understanding and does not limit the present disclosure or the scope of the claims. The scope of the present disclosure is defined by the claims, and therefore, embodiments, examples, and modifications not described herein are also included in the scope of the present disclosure.

### Supplementary Notes

The technology disclosed in the present specification can be understood as follows in one aspect.

Item 1. A gate driver circuit for driving an N-type power transistor based on a control signal, the gate driver circuit comprising:

a low-side line connected to a source of the power transistor;

an output line connected to a gate of the power transistor;

a high-side line in which a high-level voltage higher than a voltage of the low-side line is generated;

a first transistor connected between the high-side line and the output line;

a second transistor connected between the output line and the low-side line;

a third transistor connected between the output line and the low-side line in parallel with the second transistor;

a pre-driver configured to turn on the first transistor and turn off the second transistor when the control signal is at an on-level indicating to turn on the power transistor, and turn off the first transistor and turn on the second transistor when the control signal is at an off-level indicating to turn off the power transistor; and

an auxiliary circuit configured to turn on the third transistor for a predetermined period when the control signal transitions from the off-level to the on-level.

Item 2. The gate driver circuit according to item 1, wherein the auxiliary circuit includes a pulse generator configured to generate a pulse signal having a pulse width corresponding to the predetermined period.

Item 3. The gate driver circuit according to item 2, wherein a high level of the pulse signal is the high-level voltage, and the pulse signal is supplied to a gate of the third transistor.

Item 4. The gate driver circuit according to item 2, wherein the auxiliary circuit further includes a buffer having an input receiving the pulse signal and an output connected to a gate of the third transistor.

Item 5. The gate driver circuit according to item 4, wherein the buffer includes a CMOS inverter having a power supply terminal connected to the output line and an output connected to the gate of the third transistor.

Item 6. The gate driver circuit according to item 2, wherein the auxiliary circuit further includes a level shifter having an input receiving the pulse signal and an output connected to the gate of the third transistor, the level shifter being configured to level-shift a high level of the pulse signal to an intermediate-level voltage lower than the high-level voltage.

Item 7. The gate driver circuit according to item 6, wherein the level shifter includes:

a constant voltage element having a first end connected to the output line; and

a CMOS inverter having a power supply terminal connected to a second end of the constant voltage element and an output connected to the gate of the third transistor.

Item 8. The gate driver circuit according to any one of items 1 to 7, further comprising a MOS transistor connected between a drain of the third transistor and the output line and having a gate and a drain connected to each other.

Item 9. The gate driver circuit according to any one of items 1 to 8, wherein the predetermined period is 1 to 20 ns.

Item 10. The gate driver circuit according to any one of items 1 to 9, being monolithically integrated on a single semiconductor substrate.

Item 11. A switching circuit comprising:

a power transistor; and

the gate driver circuit according to any one of items 1 to 10 configured to drive the

power transistor.

What is claimed is:

1. A gate driver circuit for driving an N-type power transistor based on a control signal, the gate driver circuit comprising:
a low-side line connected to a source of the power transistor;
an output line connected to a gate of the power transistor;
a high-side line in which a high-level voltage higher than a voltage of the low-side line is generated;
a first transistor connected between the high-side line and the output line;
a second transistor connected between the output line and the low-side line;
a third transistor connected between the output line and the low-side line in parallel with the second transistor;
a pre-driver configured to turn on the first transistor and turn off the second transistor when the control signal is at an on-level indicating to turn on the power transistor, and turn off the first transistor and turn on the second transistor when the control signal is at an off-level indicating to turn off the power transistor; and
an auxiliary circuit configured to turn on the third transistor for a predetermined period when the control signal transitions from the off-level to the on-level.

2. The gate driver circuit according to claim 1, wherein the auxiliary circuit includes a pulse generator configured to generate a pulse signal having a pulse width corresponding to the predetermined period.

3. The gate driver circuit according to claim 2, wherein a high level of the pulse signal is the high-level voltage, and the pulse signal is supplied to a gate of the third transistor.

4. The gate driver circuit according to claim 2, wherein the auxiliary circuit further includes a buffer having an input receiving the pulse signal and an output connected to a gate of the third transistor.

5. The gate driver circuit according to claim 4, wherein the buffer includes a CMOS inverter having a power supply terminal connected to the output line and an output connected to the gate of the third transistor.

6. The gate driver circuit according to claim 2, wherein the auxiliary circuit further includes a level shifter having an input receiving the pulse signal and an output connected to the gate of the third transistor, the level shifter being configured to level-shift a high level of the pulse signal to an intermediate-level voltage lower than the high-level voltage.

7. The gate driver circuit according to claim 6, wherein the level shifter includes:
a constant voltage element having a first end connected to the output line; and
a CMOS inverter having a power supply terminal connected to a second end of the constant voltage element and an output connected to the gate of the third transistor.

8. The gate driver circuit according to claim 1, further comprising a MOS transistor connected between a drain of the third transistor and the output line and having a gate and a drain connected to each other.

9. The gate driver circuit according to claim 1, wherein the predetermined period is 1 to 20 ns.

10. The gate driver circuit according to claim 1, being monolithically integrated on a single semiconductor substrate.

11. A switching circuit comprising:
a power transistor; and
the gate driver circuit according to claim 1 configured to drive the power transistor.
